(19) United States
(12) Patent Application Publication
(10) Pub. No.: US 2015/0136171 A1
(43) Pub. Date: May 21, 2015

(54) LIQUID OR VAPOR INJECTION PLASMA ASHING SYSTEMS AND METHODS

(71) Applicant: Lam Research Corporation, Fremont, CA (US)

(72) Inventors: Carlo Waldfried, Middleton, MA (US); Orlando Escorcia, Falls Church, VA (US)

(73) Assignee: Lam Research Corporation, Fremont, CA (US)

(21) Appl. No.: 14/082,712

(22) Filed: Nov. 18, 2013

(51) Int. Cl. H01L 21/311; H01J 37/32

(52) U.S. Cl. CPC H01L 21/31138; H01J 37/32009; H01J 37/32431; H01J 2237/335
USPC 134/1.1; 156/345.1; 156/345.26

(57) ABSTRACT

A plasma ashing system includes a process chamber including a substrate. A carrier gas supply supplies a carrier gas to the processing chamber. A plasma source is configured to create plasma to the process chamber. A liquid injection source is configured to at least one of inject a compound into the plasma or supply the compound into the plasma. The compound is normally a liquid at room temperature and at atmospheric pressure. A controller is configured to control the liquid injection source, to expose the substrate to the plasma for a predetermined period and to purge reactants from the processing chamber after the predetermined period.

### FIELD

The present disclosure relates to plasma ashing, and more particularly to plasma ashing including liquid or vapor injection into the plasma to create new reactive species.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Some integrated circuit (IC) devices require minimum substrate damage and little or no oxidation during plasma photoresist stripping processes. Some new technologies, such as high-dose, ultra-shallow junction implants for source/drain extensions, 3D integration schemes and processes involving new materials such as high K/metal gate and SiGe, pose new challenges to advanced photoresist processes. In addition, shrinking photoresist thicknesses, new photoresist materials, and the use of aggressive multi-species implant dose conditions also increase the difficulty when performing post-implant residue removal.

Oxidizing or fluorine-containing plasma strip approaches, while effective for residue removal, often cause unacceptable substrate loss and dopant bleaching. Fluorine-free, O₂-forming gas (N₂/H₂) based downstream plasma strip processes may cause significant silicon oxidation (˜1 Å oxide growth per cleaning step) due to plasma exposure and do not offer sufficient residue removal efficacy.

Oxygen-free plasmas formed from reducing chemistries that typically employ forming gas (N₂/H₂), optionally with a high percentage of H₂, offer low substrate oxidation. However, this approach has low resist removal rates, plasma-induced changes to the dopant distribution, and limited residue removal capability.

Plasmas with a controlled mix ratio of active oxygen (O*) and active nitrogen (N*) species, such as N₂O— or NH₃-based plasmas, provide excellent front end of line (FEOL) cleaning solutions. These plasmas offer acceptable resist removal rates, low Si oxidation, little impact on dopant distribution profiles and good residue removal capability. However these approaches may limit residue removal efficiency and throughput for some post implant strip or advanced integration processes.

### SUMMARY

A plasma ashing system according to the present disclosure includes a process chamber including a substrate. A carrier gas supply provides a carrier gas to the processing chamber. A plasma source is configured to create plasma to the process chamber. A liquid injection source is configured to at least one of inject a compound into the plasma or supply the compound into the plasma. The compound is normally a liquid at room temperature and at atmospheric pressure. A controller is configured to control the liquid injection source, to expose the substrate to the plasma for a predetermined period and to purge reactants from the processing chamber after the predetermined period.

A method for ashing a substrate includes arranging a substrate in a processing chamber; supplying a carrier gas to the processing chamber; creating plasma in the processing chamber; at least one of injecting a compound into the plasma and supplying the compound into the plasma, wherein the compound is normally a liquid at room temperature and at atmospheric pressure; exposing the substrate to the plasma for a predetermined period; and removing reactants from the processing chamber after the predetermined period.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a plasma processing chamber including a liquid injection system according to the present disclosure;

FIG. 1B is a functional block diagram of an example of another liquid injection system for a plasma processing chamber according to the present disclosure;

FIG. 2 is a flowchart illustrating an example of a method for liquid injection plasma ashing according to the present disclosure;

FIG. 3 is an optical emission spectrograph for plasma generated with argon alone and argon with IPA injection according to the present disclosure;

FIG. 4 is an optical emission spectrograph for plasma generated with forming gas (such as 97% N₂ and 3% H₂) alone and forming gas with IPA injection according to the present disclosure;

FIG. 5 is an optical emission spectrograph for plasma generated with NH₃/O₂ alone and NH₃/O₂ with IPA injection according to the present disclosure;

FIG. 6 is an optical emission spectrograph for plasma generated with argon alone and argon with peroxide injection according to the present disclosure; and

FIG. 7 is an optical emission spectrograph for plasma generated with nitrogen N₂ alone and nitrogen N₂ with peroxide injection according to the present disclosure.

In the drawings, reference numbers may be reused to identify similar and/or identical elements.

### DETAILED DESCRIPTION

The present disclosure describes systems and methods for liquid injection plasma ashing with improved resist and residue removal capability and with superior substrate loss performance for advanced dry strip applications.

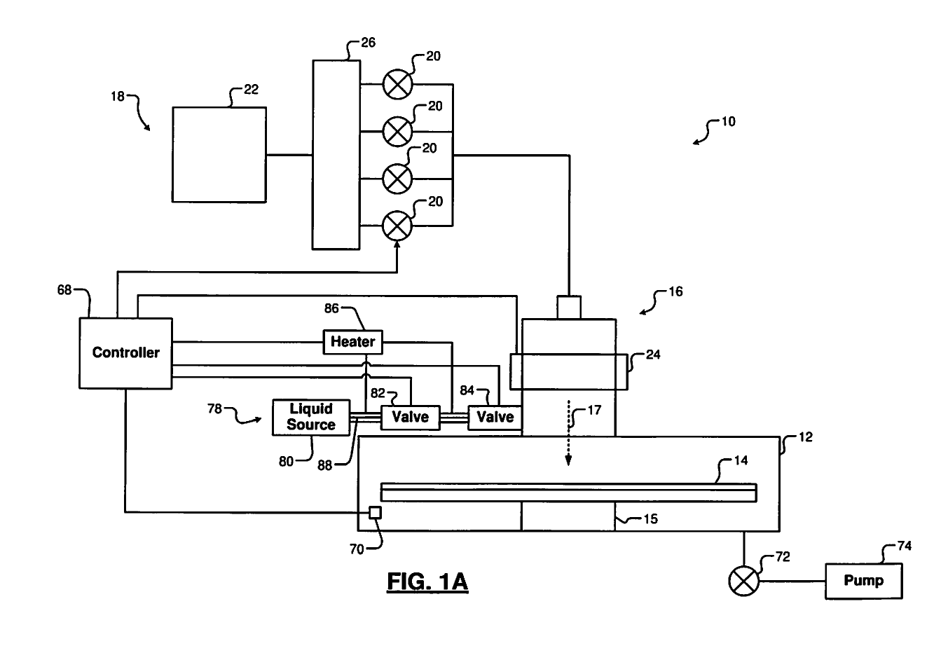

Referring now to FIG. 1, an example of a suitable substrate processing system 10 is shown. The system 10 includes a process chamber 12 for processing a substrate 14 arranged on a pedestal or other support identified at 15. A plasma source 16 delivers excited state gas or plasma 17 into the process chamber 12 to produce a reactive environment therein. A gas delivery system 18 includes a plurality of gas valves (and/or mass flow controllers) 20 for selectively delivering at least one gas from a gas supply 22 to the plasma source 16. A power generator assembly 24 powers the plasma source 16 to excite the gas delivered by the gas delivery system 18.

The substrate processing system 10 may include any type of plasma asher or other system. For example, a plasma asher employing an inductively coupled plasma reactor or a downstream plasma asher may be used. Other suitable plasma ashers include, but are not limited to, electron cyclotron residence (ECR) systems, radio frequency (RF) systems, hybrid systems, or other suitable systems. In one example, the plasma asher is a downstream plasma asher, such as for example, a microwave plasma asher.

A controller 68 may sense operating parameters such as chamber pressure and temperature inside the process chamber using one or more sensors 70. A vacuum pump 74 typically draws process gases out of the process chamber 12 and maintains a suitably low pressure within the reactor by a flow restriction device, such as a restriction valve 72. The controller 68 may also control the valves and/or mass flow controllers 20 as well as other components of the system 10.

In some examples, a liquid injection system 78 injects liquid into the plasma. The liquid injection system 78 includes a liquid source 80, a shut off valve 82, and a valve 84 to control the amount of added liquid/vapor substance. A heater 86 may be provided to heat lines 88 between the liquid source 80 and the shutoff valve 82, the valve 84 and the plasma source 16 (or the process chamber 12).

The shut off valve 82 may be used to stop the liquid flow when desired and may include a remotely triggered and pneumatically or electrically controlled shut off valve. In some examples, the valve 84 may include a fine-adjustable needle valve. The liquid may include water, alcohol, hydrazine, peroxide, benzene, or other suitable liquid. While the liquid is shown being introduced at the plasma source 16, the liquid can be introduced directly into the plasma in the process chamber 12 and/or in other suitable ways.

In FIG. 1 B, another example of a liquid injection system 90 is shown. The liquid is pressurized using a pump 92. The liquid enters the plasma through a spray nozzle or injector 94. In some examples, the nozzle or injector 94 provides a mist of micro-droplets similar to a fuel injection system of a car engine. This allows for precise metering of the amounts of liquid that is being injected as well as improved control of injection timing.

One benefit of generating plasma with injected liquids is to provide novel plasma chemistries, new plasma radicals and/or novel mix ratios of plasma active species that can be helpful for one or more of the following: (1) improved resist removal capability, (2) improved substrate loss characteristics, (3) improved implant crust and residue removal capability, (4) improved Si, SiN, SiGe, oxide or metals oxidation, (5) improved dopant retention performance, etc.

In some examples, the liquid injection plasma ashing according to the present disclosure includes a mix of a carrier gas and compound that is normally (at room temperature and at atmospheric pressure) in liquid form. The compound is introduced into the plasma as a vapor or injected as a liquid. As a result of the lower pressure, higher temperature, and/or energy supplied by the plasma, the compound dissociates into new reactive species. In some examples, the carrier gas includes at least one of argon (Ar), helium (He), molecular nitrogen (N₂), forming gas (FG) (such as for example, 97% N₂ and 3% H²), molecular oxygen (O₂), ammonia (NH₃), molecular hydrogen (H₂), or other carrier gas. The mix may optionally include a reactive gas. The reactive gas may include at least one of molecular oxygen (O₂), molecular hydrogen (H₂), ammonia (NH₃), CₓF_{y}, CₓH_{y}, carbon monoxide (CO), carbon dioxide (CO₂), nitrous oxide (N₂O), nitrogen triflouride (NF₃), or other reactive gas (where x and y are integers).

The plasma generated from this mixture produces new plasma species that are unique (in type, composition, mix ratio, abundance, etc.). The benefit of the introduction of the new species includes one or more of improved resist removal rates, reduced substrate loss, improved residue and polymer removal rates, improved dopant retention performance, and/or improved device performance or yield.

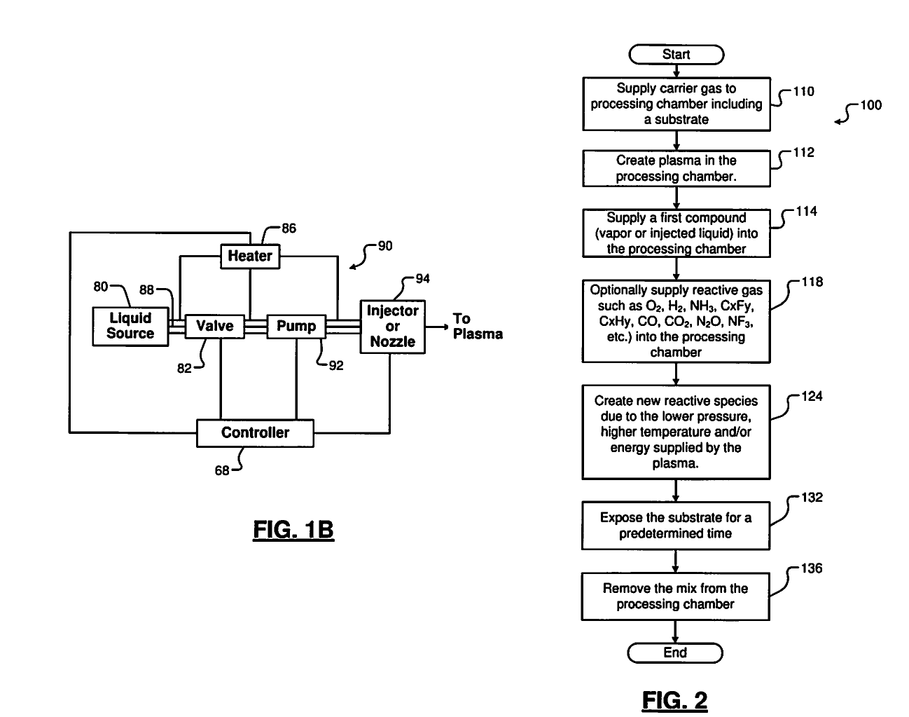

Referring now to FIG. 2, an example of a method 100 for liquid injection plasma ashing according to the present disclosure is shown. At 110, a carrier gas is supplied to a processing chamber including a substrate. At 112, plasma is created in the processing chamber. At 114, a first liquid compound (vapor or injected liquid) is supplied to the processing chamber. In some examples, the carrier gas may include Ar, He, N₂, FG, O₂, NH₃, H₂, etc. At 118, a reactive gas is optionally supplied into the processing chamber. For example, the reactive gas may include O₂, H₂, NH₃, CxFy, CxHy, CO, CO₂, N₂O, NF₃, etc. (where x and y are integers).

At 124, the mix is disassociated into one or more new reactive species (as compared to the plasma without the compound) due to the lower pressure, higher temperature and/or energy supplied by the plasma. At 132, the substrate is exposed for a predetermined period. At 136, reactants are removed from the processing chamber by purging or evacuating the chamber.

### EXAMPLE 1

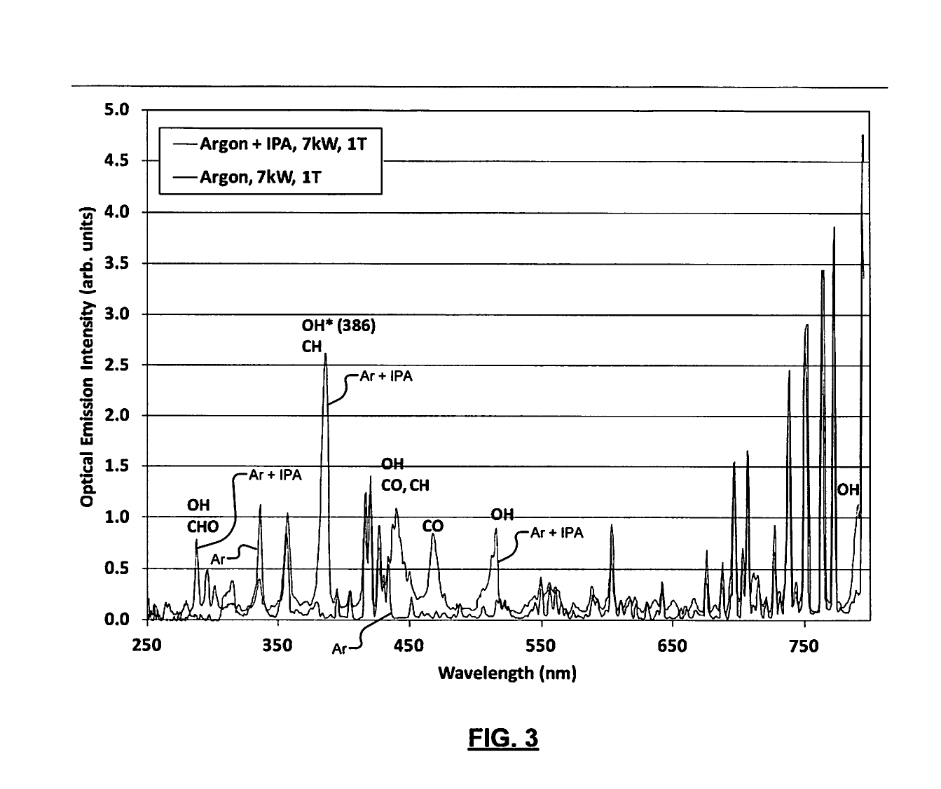

Referring now to FIG. 3, an example of an optical emission spectrograph is shown for plasma generated with argon alone and argon with liquid or vapor isopropyl alcohol (IPA) injection. The plasma was generated by adding small amounts of liquid or vapor IPA, which has the chemical structure (CH₃)₂(CH)(OH) to a carrier gas flow of 7 slm argon at 1 Torr and 4 kW microwave power. Optical emission spectroscopy reveals the unique plasma signatures of the IPA by comparing the emission spectra with and without the IPA. As shown in FIG. 3, the IPA produces unique plasma emission features that can be identified as CH*, OH*, and potentially CO and CHO* reactive species.

### EXAMPLE 2

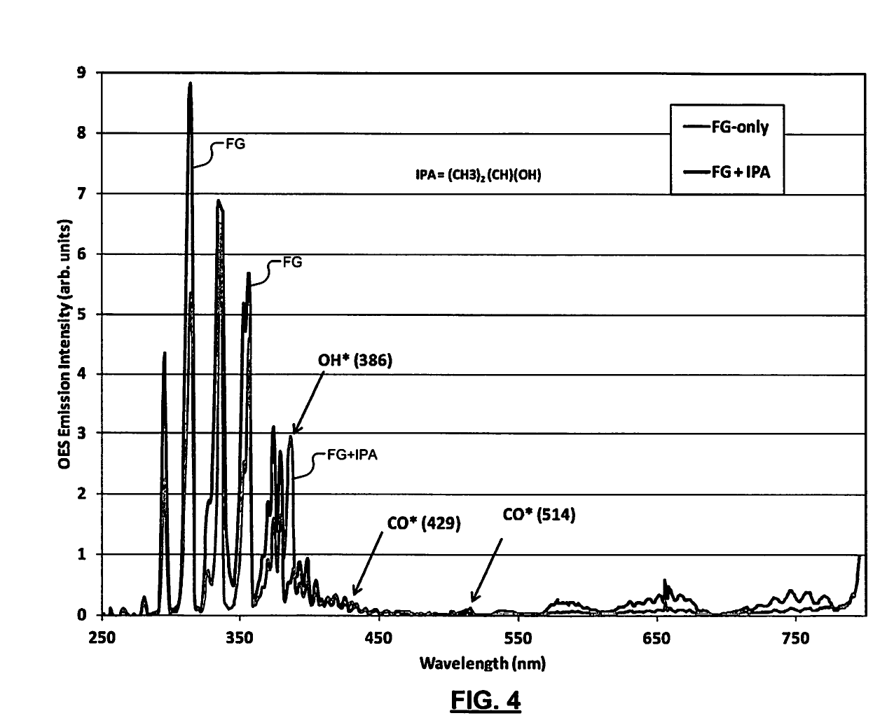

Referring now to FIG. 4, an example of an optical emission spectrograph is shown for plasma generating with forming gas (97% N₂ and 3% H₂) alone and forming gas with liquid or vapor IPA injection. The plasma was generated by adding small amounts of liquid or vapor IPA to a carrier gas flow of 7 slm forming gas (97% N₂ and 3% H₂) at 1 Torr and 3.5 kW microwave power. Optical emission spectroscopy reveals the unique plasma signatures of the IPA by comparing the emission spectra with and without the IPA. As shown in FIG. 4, the IPA produces unique plasma emission features that can be identified as OH*, and potentially some CO* reactive species.

### EXAMPLE 3

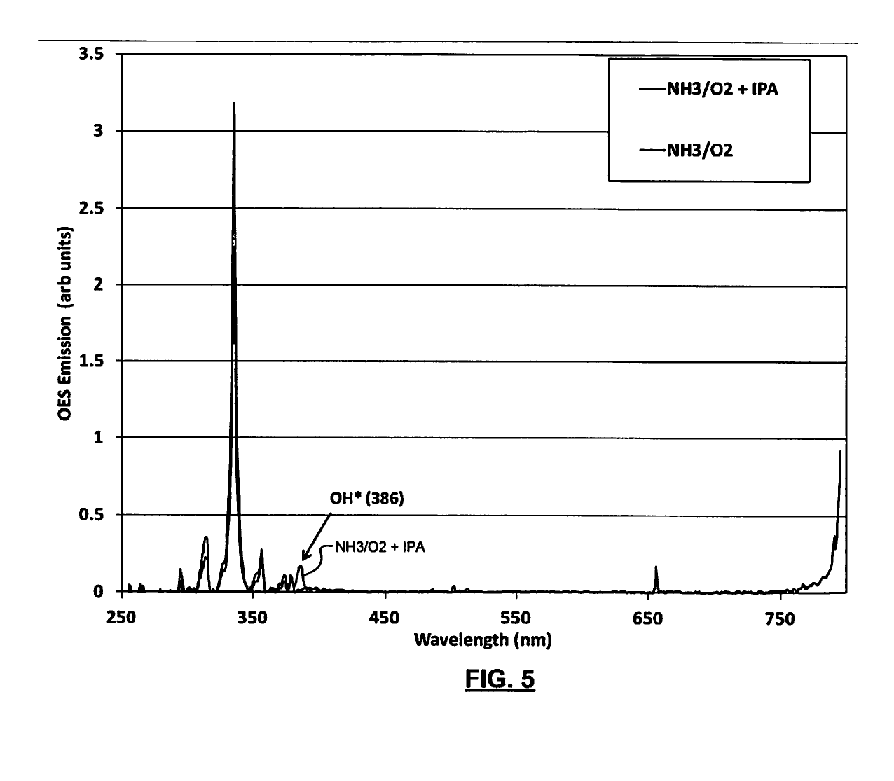

Referring now to FIG. 5, an optical emission spectrograph is shown for plasma generating with NH₃/O₂ alone and NH₃/O₂ with liquid or vapor IPA injection. The plasma was generated by adding small amounts of liquid or vapor IPA to a carrier gas flow of 90% NH₃ and 10% O₂ at a flow rate of 7 slm and at a chamber pressure of 1 Torr and microwave power of 3.5 kW. FIG. 5 shows optical emission spectra, comparing NH₃/O₂ and NH₃/O₂ with added IPA, indicating that the IPA additives produce plasma emission features at a wavelength of 386 nm that can be identified as OH* reactive species.

### EXAMPLE 4

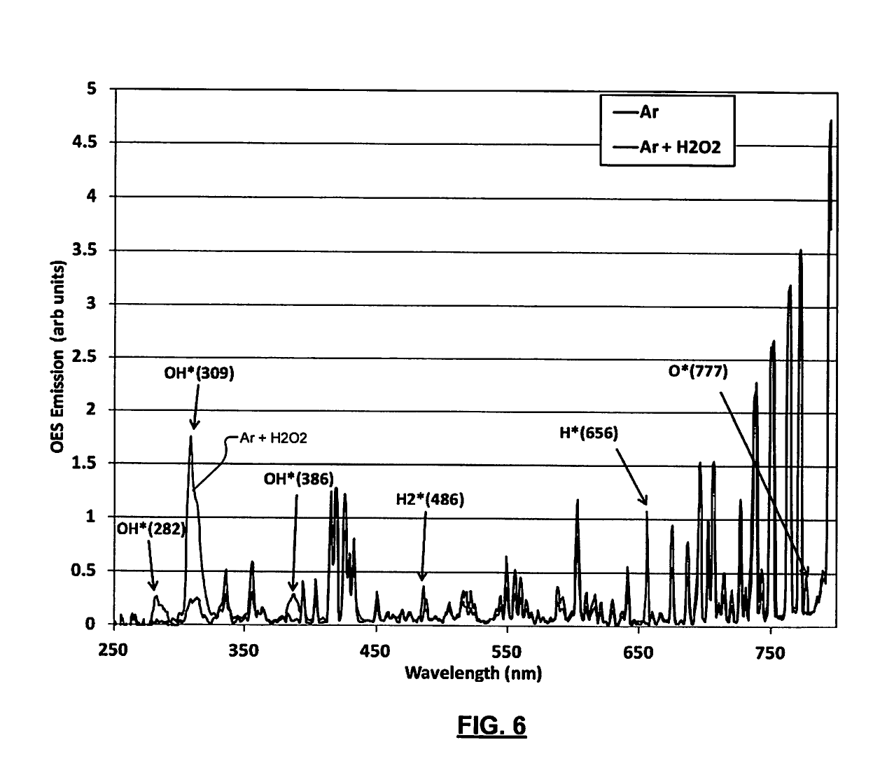

Referring now to FIG. 6, an optical emission spectrograph is shown for plasma generating with argon alone and argon with liquid or vapor hydrogen peroxide injection. Plasma was generated by adding small amounts of liquid or vapor hydrogen peroxide (H₂O₂) to a carrier gas flow of 7 slm argon at 1 Torr and 3.5 kW microwave power. Optical emission spectroscopy reveals the unique plasma signatures of the peroxide by comparing the emission spectra with and without the peroxide additive. As shown in FIG. 6, the peroxide produces unique plasma emission features that can be identified as OH* reactive species (emission features at 282 nm, 309 nm and 386 nm), as well as H* (emission feature at 656 nm), H₂* (emission feature at 486 nm), and O* (emission feature at 777 nm).

### EXAMPLE 5

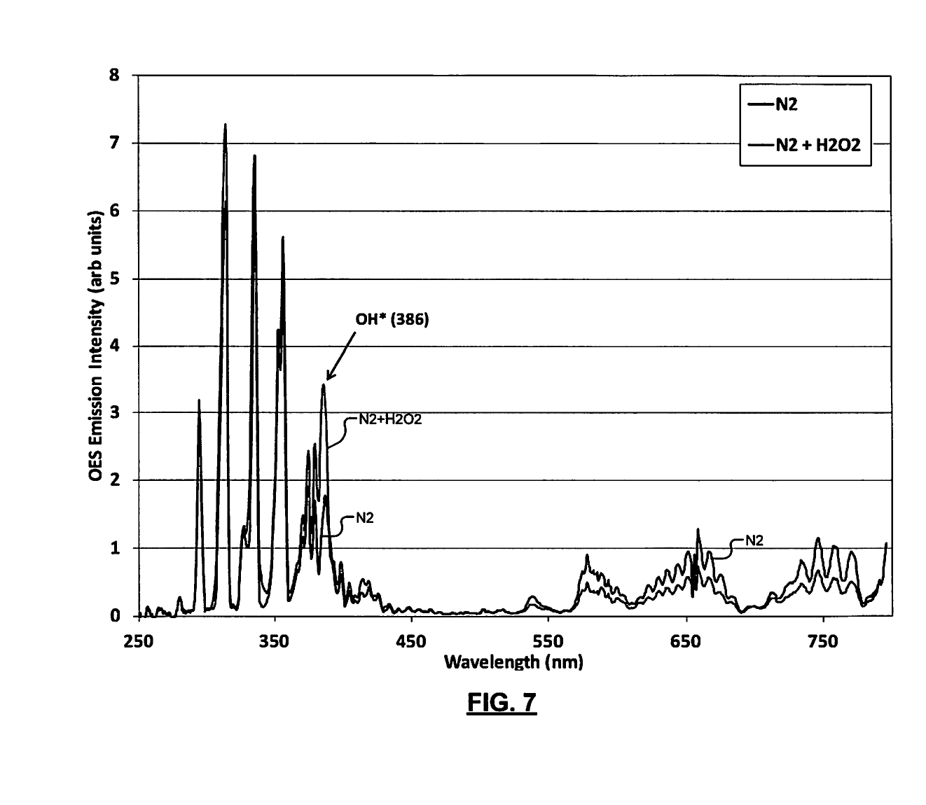

Referring now to FIG. 7, an optical emission spectrograph is shown for plasma generating with nitrogen N₂ alone and nitrogen N₂ with liquid or vapor hydrogen peroxide injection. Plasma was generated by adding small amounts of liquid or vapor hydrogen peroxide (H₂O₂) to a carrier gas flow of 7 slm nitrogen at 1 Torr and 3.5 kW microwave power. FIG. 7 shows optical emission spectra, comparing N₂ and N₂ with added H₂O₂, indicating that the H₂O₂ additives produce a plasma emission feature at a wavelength of 386 nm that can be identified as OH* reactive species.

### EXAMPLE 6

Photoresist removal rates were measured for nitrogen and NH₃/O₂ (90% NH₃, 10% O₂) plasma, chemistries with and without added liquid or vapor injection additives of IPA and H₂O₂. The resist removal rate was determined with a 1.8 mm thick AZ1512 I-line photoresist and with a plasma exposure of 30 s at 275° C. wafer temp at 1 Torr and 7 slm TGF of the carrier gas. The Table I below shows the results, indicating significant response from the additives. It should be noted that a lower ash rate could potentially be of benefit for improved crust and residue removal capability.

TABLE I

| Chemistry | Ash Rate (μm/min) |
|---|---|
| N₂ | 0.80 |
| N₂ + IPA | 0.90 |
| N₂ + H₂O₂ | 0.79 |
| 90% NH₃/O₂ | 1.2 |
| 90% NH₃/O₂ + IPA | 0.94 |
| 90% NH₃/O₂ + H₂O₂ | 1.21 |

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

In this application, including the definitions below, the term controller may be replaced with the term circuit. The term controller may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term shared processor encompasses a single processor that executes some or all code from multiple controllers. The term group processor encompasses a processor that, in combination with additional processors, executes some or all code from one or more controllers. The term shared memory encompasses a single memory that stores some or all code from multiple controllers. The term group memory encompasses a memory that, in combination with additional memories, stores some or all code from one or more controllers. The term memory may be a subset of the term computer-readable medium. The term computer-readable medium does not encompass transitory electrical and electromagnetic signals propagating through a medium, and may therefore be considered tangible and non-transitory. Non-limiting examples of a non-transitory tangible computer readable medium include nonvolatile memory, volatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

What is claimed is:

1. A method for ashing a substrate, comprising:
arranging a substrate in a processing chamber;
supplying a carrier gas to the processing chamber;
creating plasma in the processing chamber;
at least one of:
injecting a compound into the plasma; and
supplying the compound into the plasma,
wherein the compound is normally a liquid at room temperature and at atmospheric pressure;
exposing the substrate to the plasma for a predetermined period; and
removing reactants from the processing chamber after the predetermined period.

2. The method of claim 1, wherein as a result of at least one of a lower pressure in the processing chamber, a higher temperature in the processing chamber or energy supplied by the plasma, new reactive species are created in the plasma from the compound.

3. The method of claim 1, wherein the carrier gas includes at least one of a noble gas, a nitrogen-bearing gas, a hydrogen-bearing gas, and an oxygen-bearing gas.

4. The method of claim 1, wherein the carrier gas includes a gas mixture including at least one of forming gas, ammonia, methane, nitrous oxide, carbon-dioxide or carbon-monoxide.

5. The method of claim 4, wherein the forming gas includes molecular nitrogen and molecular hydrogen.

6. The method of claim 1, wherein the compound includes at least one of water, alcohol, hydrazine, peroxide, and benzene.

7. The method of claim 1, further comprising supplying a reactive gas into the processing chamber.

8. The method of claim 7, wherein the reactive gas includes at least one of molecular oxygen, molecular hydrogen, ammonia, CₓF_{y}, CₓH_{y}, carbon monoxide, carbon dioxide, nitrous oxide, and nitrogen triflouride and wherein x and y are integers.

9. The method of claim 1, wherein the reactants are removed using at least one of evacuation and purging.

10. The method of claim 1, wherein the compound includes one of isopropyl alcohol and hydrogen peroxide.

11. The method of claim 1, wherein:
the carrier gas includes one of argon, forming gas, and a mixture of ammonia and oxygen; and
the compound includes isopropyl alcohol.

12. The method of claim 1, wherein:
the carrier gas includes one of argon and molecular nitrogen; and
the compound includes hydrogen peroxide.

13. The method of claim 1, wherein:
the carrier gas includes molecular nitrogen; and
the compound includes one of isopropyl alcohol and hydrogen peroxide.

14. The method of claim 1, wherein:
the carrier gas includes a mixture of ammonia and oxygen; and
the compound includes one of isopropyl alcohol and hydrogen peroxide.

15. A plasma ashing system, comprising:
a process chamber including a substrate;
a carrier gas supply to supply a carrier gas to the processing chamber;
a plasma source configured to create plasma to the process chamber; and
a liquid injection source configured to at least one of:
inject a compound into the plasma; and
supply the compound into the plasma,
wherein the compound is normally a liquid at room temperature and at atmospheric pressure.

16. The plasma ashing system of claim 15, further comprising a controller configured to control the liquid injection source, to expose the substrate to the plasma for a predetermined period and to purge reactants from the processing chamber after the predetermined period.

17. The plasma ashing system of claim 15, wherein as a result of at least one of a lower pressure in the processing chamber, a higher temperature in the processing chamber or energy supplied by the plasma, new reactive species are created in the plasma by the compound.

18. The plasma ashing system of claim 15, wherein the carrier gas includes at least one of a noble gas, a nitrogen-bearing gas, a hydrogen-bearing gas, and an oxygen-bearing gas.

19. The plasma ashing system of claim 15, wherein the carrier gas includes a gas mixture including at least one of forming gas, ammonia, methane, nitrous oxide, carbon-dioxide or carbon-monoxide.

20. The plasma ashing system of claim 19, wherein the forming gas includes molecular nitrogen and molecular hydrogen.

21. The plasma ashing system of claim 15, wherein the compound includes at least one of water, alcohol, hydrazine, peroxide, and benzene.

22. The plasma ashing system of claim 16, wherein the controller is configured to supply a reactive gas into the processing chamber.

23. The plasma ashing system of claim 22, wherein the reactive gas includes at least one of molecular oxygen, molecular hydrogen, ammonia, CₓF_{y}, CₓH_{y}, carbon monoxide, carbon dioxide, nitrous oxide, and nitrogen triflouride and wherein x and y are integers.

24. The plasma ashing system of claim 16, wherein the controller is configured to remove the reactants using at least one of evacuation and purging.

25. The plasma ashing system of claim 15, wherein the compound includes one of isopropyl alcohol and hydrogen peroxide.

26. The plasma ashing system of claim 15, wherein:
the carrier gas includes one of argon, forming gas, and a mixture of ammonia and oxygen; and
the compound includes isopropyl alcohol.

27. The plasma ashing system of claim 15, wherein:
the carrier gas includes one of argon and molecular nitrogen; and
the compound includes hydrogen peroxide.

28. The plasma ashing system of claim 15, wherein:
the carrier gas includes molecular nitrogen; and
the compound includes one of isopropyl alcohol and hydrogen peroxide.

29. The plasma ashing system of claim 15, wherein:
the carrier gas includes a mixture of ammonia and oxygen; and
the compound includes one of isopropyl alcohol and hydrogen peroxide.
